(19) United States
(12) Patent Application Publication
(10) Pub. No.: US 2013/0119538 A1
(43) Pub. Date: May 16, 2013

(54) WAFER LEVEL CHIP SIZE PACKAGE

(71) Applicant: Robert Fabian McCarthy, Dallas, TX (US)

(72) Inventor: Robert Fabian McCarthy, Dallas, TX (US)

(73) Assignee: Texas Instruments Incorporated, Dallas, TX (US)

(21) Appl. No.: 13/297,699

(22) Filed: Nov. 16, 2011

(51) Int. Cl. H01L 23/498; H01L 21/50; H01L 21/56

(52) U.S. Cl. 257/738; 438/118; 438/113; 257/E23.069; 257/E21.499; 257/E21.502

(57) ABSTRACT

A method of making a wafer level chip size package (WCSP) comprising providing a die having a first face with a plurality of bond pads thereon, a second face opposite the first face and a plurality of side faces extending between the first face and the second face, at least one of the plurality of side faces having saw induced microcracks therein; and coating at least one of the plurality of side faces with a thin veneer of adhesive that penetrates the microcracks. A WCSP produced by the method is also disclosed.

### BACKGROUND

Integrated circuits, also referred to as “IC's” or “semiconductor chips” or simply “chips,” are electronic circuits made by diffusion of trace elements into the surface of thin substrates of semiconductor material. Integrated circuits were first produced in the mid 20^{th} Century. Because of their small size and relatively low production cost, integrated circuits are now used in most modern electronics. Semiconductor chips are typically mass produced in the form of a single wafer that contains a large number of identical integrated circuits. The wafer is cut (“singulated”) into a number of individual semiconductor chips referred to as “dies” or “dice.”

Dies are “packaged” to prevent damage to the dies and to facilitate attachment of the dies to circuit boards. Various packaging materials and processes have been used to package integrated circuit dies. One conventional packaging method involves mounting individual dies in a predetermined pattern on a substrate strip. The dies mounted on the substrate strip are then encapsulated in a plastic material, such as by a transfer molding process. Next, the encapsulated dies are singulated into individual integrated circuit packages by cutting the encapsulated die/substrate strip in accordance with the predetermined die mounting pattern. Typical cutting tools include saws and punches. Each integrated circuit package generally includes at least one die and the underlying portion of the substrate strip on which it was mounted, as well as encapsulating material which typically covers the die. The underlying substrate strip is sometimes a lead frame to which the die is electrically connected and which, in turn, is adapted to be connected to a printed circuit board (“PC” board).

Over the years, integrated circuits and the circuit boards to which they are attached have become physically smaller and more complex. One relatively new technology is known alternately as “wafer level chip scale packaging” or “wafer level chip size packaging” and other similar names (“WCSP”). Using WCSP packaging, unpackaged dies, i.e., dies with no surrounding layer of protective encapsulation, are mounted on printed circuit boards. Structure needed for electrical connection of dies to a printed circuit board are usually fabricated on one surface of the dies while the dies are still integrally connected together in a single wafer. For example, in one form of WCSP packaging, various layers including electrical contact pads and then solder bumps are formed on dies at the wafer level. After wafer singulation such dies may be attached, solder bump side down, to a PC board. Such WCSP dies have the advantage of being considerably smaller than conventionally packaged IC dies and are thus ideal for applications, such as cellular phones and digital tablets, where the associated PC boards must have a small footprint.

### BRIEF DESCRIPTION OF THE DRAWINGS

FIG. 1 is a perspective view of a wafer level chip size package (WCSP) with bump solder balls.

FIG. 2 is a detail cross-sectional view of a portion of the WCSP of FIG. 1.

FIG. 3 is a cross-sectional view of a WCSP with a microcrack in a side wall thereof.

FIG. 4 is a detailed view of a portion of the WCSP of FIG. 3.

FIG. 5 is a WCSP with a thin veneer of adhesive coating the top face and side faces thereof.

FIG. 6 is a detail of the WCSP of FIG. 5.

FIG. 7 is a perspective view of a plurality of post singulation WCSP dies mounted on a carrier substrate.

FIG. 8 is a perspective view of the WCSP dies and carrier substrate of FIG. 7 after encapsulation of the dies to form an encapsulation wafer.

FIG. 9 is a cross-sectional view of a portion of the encapsulation wafer and carrier substrate of FIG. 8.

FIG. 10 is a cross-sectional view of the encapsulation wafer of FIG. 9 with the carrier substrate removed.

FIG. 11 is a cross-sectional view of the encapsulation wafer of FIG. 10 with bumps solder balls attached to individual WCSP dies therein.

FIG. 12 is a cross-sectional view of a plurality of WCSP's after singulation from the encapsulation wafer.

FIG. 13 is a perspective view of the encapsulation wafer of FIG. 11 showing the singulation saw streets.

FIG. 14 is a flow chart of a method of making a WCSP.

### DETAILED DESCRIPTION

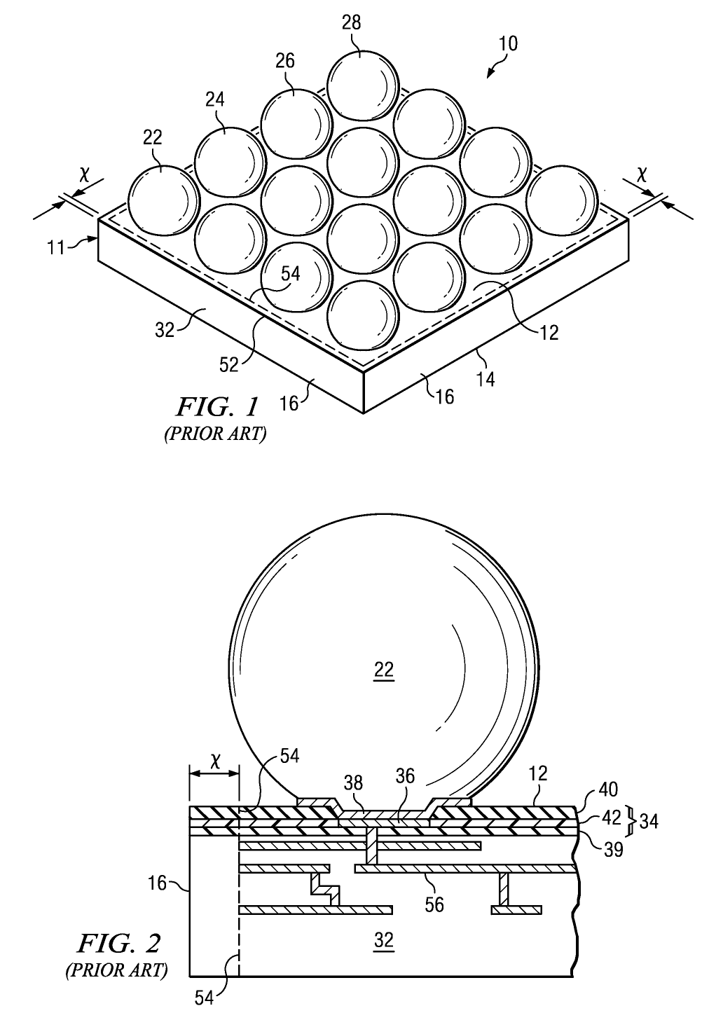

As shown by FIG. 1, a prior art wafer level chip size package (WCSP) 10 includes a typically regular parallelepiped shape (square box shape) die 11. The WCSP die 11 has a first face 12 with a plurality of bond pads thereon (not visible in FIG. 1). This first face 12 is referred to as the active side of the WCSP die 11. The WCSP die 11 has a second face 14 positioned opposite the first face 12 and a plurality of lateral side faces 16 extending between the first face 12 and the second face 14. The WCSP die 11 has a dielectric layer 32 which in many cases is formed from a low-K silicon that is very brittle. An active side electrical connection layer 34 is formed on the dielectric layer 32 at the first face 12 of the WCSP as best shown in FIG. 2. This active side connection layer 34 typically includes a plurality of bond pads 36, an under bump metal layer 38 in electrical contact with the bond pad 36 and at least a first passivation layer 40 and usually a second passivation layer 42 separating the under bump metal layer 38 from the dielectric layer 32. A device or “customer” passivation layer 39 may be positioned under the second passivation layer 42 to further electrically isolate the under bump metal layer 38 from the dialectic layer. Various materials with various thicknesses have been used for the above described layers. In one typical example, bond pads 36 are formed primarily from Cu with a TiWCu base for adhesion and may have a thickness of about 10¹⁰ Angstroms; the under bump metal (also known as the “redistribution layer”) may be also be TiWCu, Cu and may have a thickness of about 0.010 mm. The passivation layers 40, 42 may each have a thickness of about 0.0075 mm and may be made of polyimide. A typical total die thickness, excluding the solder balls, may be about 0.33 mm. Bump solder balls 22, 24, 26, 28, etc., which may have a typical post attachment height of about 0.185 mm, are physically and electrically connected to corresponding under bump metal layers 38 which are electrically connected to bond pads 36. The bond pads, in turn, are electrically connected to interior circuitry 56 which is typically arranged in a plurality of interconnected circuit layers positioned within the dielectric layer 32.

As illustrated best in FIG. 1, the WCSP first face 12 has a square outer peripheral edge 52. Positioned inwardly of this outer peripheral edge 52 is the outer periphery 54 of the interior circuitry region 56. In other words, periphery 54, which is generally congruent to outer peripheral edge 52, represents the outer physical boundary of the interior circuitry 56. The interior circuitry 56 thus stops at a distance “x” from each side face 16. This distance x may vary from package to package but may typically be in a range of about 5 μm to 30 μm. The above described exemplary WCSP structure is known in the art.

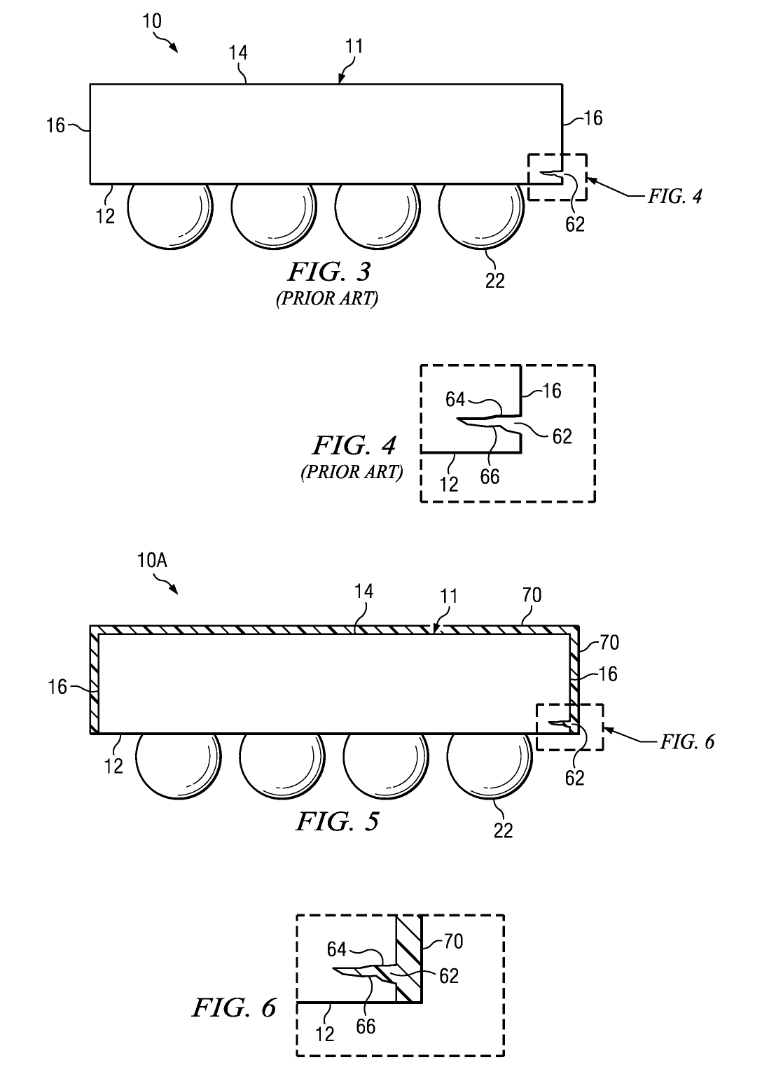

FIG. 3 is a cross-sectional view of a WCSP 10 having a microcrack 62 in a side wall 16 thereof. FIG. 4 is a detail view of microcrack 62. A typical microcrack 62 may have a gap distance between opposite sidewalls 64, 66 thereof of less than 1 μm to about 5 μm. Microcracks such as 62 often occur in low-K dielectric layers 32 as a result of wafer singulation sawing. Applicant has discovered that such microcracks 62, although often not causing problems immediately, tend to propagate inwardly as a result of downstream handling and testing of the WCSP 10 or mounting, testing or use of the WCSP on a customer circuit board. Applicant's research suggests that this microcrack propagation is a result of physical stress on the WCSP after singulation. If a microcrack 62 propagates into the interior circuitry 56, it may cause damage to the internal circuitry 56 resulting in electrical failure. Since such electrical failure typically does not occur immediately, and often not even after manufacturer testing, WCSP's are sometimes sold to customers, mounted on their circuit boards and tested and used before the defect becomes manifest. Thus, ironically, much of the WCSP testing used to detect faults may actually contribute to microcrack propagation, which causes circuit failures after the chip is placed into use by the customer.

Applicant has discovered that such circuit failures associated with microcracks 62 may be prevented by applying a thin veneer of adhesive to one or more of the surfaces where such microcracks 62 are most likely to occur. In one embodiment, as shown in FIG. 5, the adhesive veneer 70 is applied to each of the side faces 16 and the second face 14 of the WCSP. The veneer of adhesive 70 penetrates into the microcrack 62, FIG. 6, causing the sidewalls 64, 66 of the microcrack 62 to be adhered together. With the sidewalls of the microcrack 62 adhered together, the microcrack 62 ceases to propagate and, therefore, does not reach the interior circuitry 56. The microcrack is thus prevented from causing chip failure. A WCSP having such an adhesive layer 70 is referenced herein as WCSP 10A. The structure of WCSP 10A may be identical to that described for WCSP 10 shown in FIGS. 1 and 2, except for the veneer of adhesive 70. Thus, the same reference numerals will be used to reference the structure of WCSP 10A as for WCSP 10, except with regard to the veneer of adhesive 70.

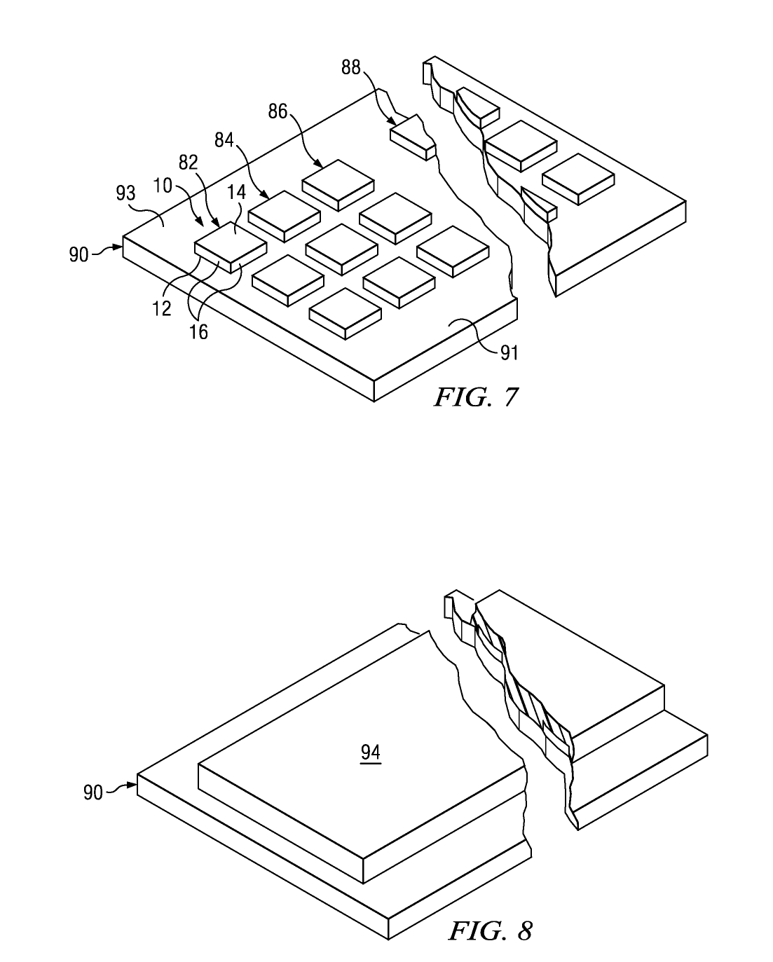

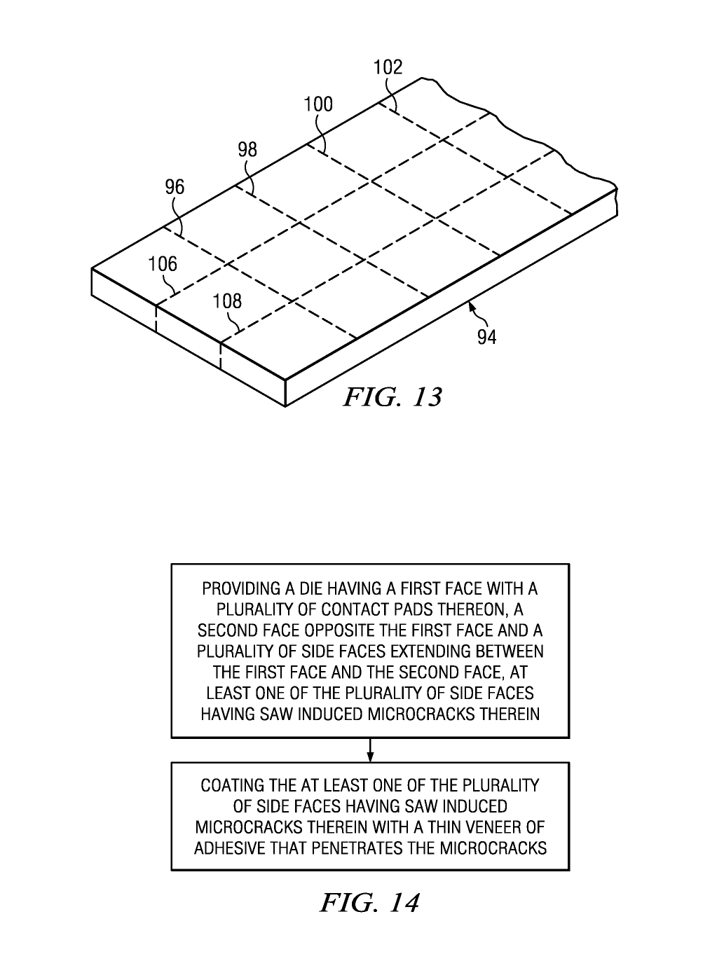

One method of making a WCSP 10A with a thin veneer of adhesive 70 coating the second face 14 and side faces 16 of the die 11 is illustrated in FIGS. 7 through 14. As with the prior art, dies 11 are initially formed in a single wafer (not shown) which is processed to form various active face layers 34, which may be the same as discussed in reference to FIGS. 1 and 2 above; except that solder bumps 22, 24, etc. are not formed on face 12. Thus the structure of the dies on the wafer when the first face forming process is completed may be the same as shown in FIGS. 1 and 2, except that there are no solder bumps 22, etc. The wafer is then singulated into a plurality of “bumpless” dies. As illustrated in FIG. 7, after singulation from the wafer, these bumpless WCSP dies 82, 84, 86, 88, etc., may be mounted, active face 12 down, in a rectangular grid pattern on a carrier substrate 90. The carrier substrate 90 may be, for example, polyimide wafer tape or another material from which the dies can be easily removed in a subsequent process. The carrier substrate may have peripheral rail portions 91, 93 which are adapted to be received between the upper and lower halves of a mold to hold the carrier substrate 90 in a proper position within the mold cavity.

The carrier substrate 90 with dies 82, 84, etc. mounted thereon is positioned in a mold cavity (not shown) such as, for example, a transfer mold cavity, where molten encapsulation material such as epoxy mold compound is applied to the carrier substrate 90 and dies 82, 84, etc. The encapsulation of dies and the like through transfer molding is well known in the art and will thus not be further described herein. The encapsulation material, in its molten state, must have a viscosity sufficiently low to penetrate into the microcracks 62.

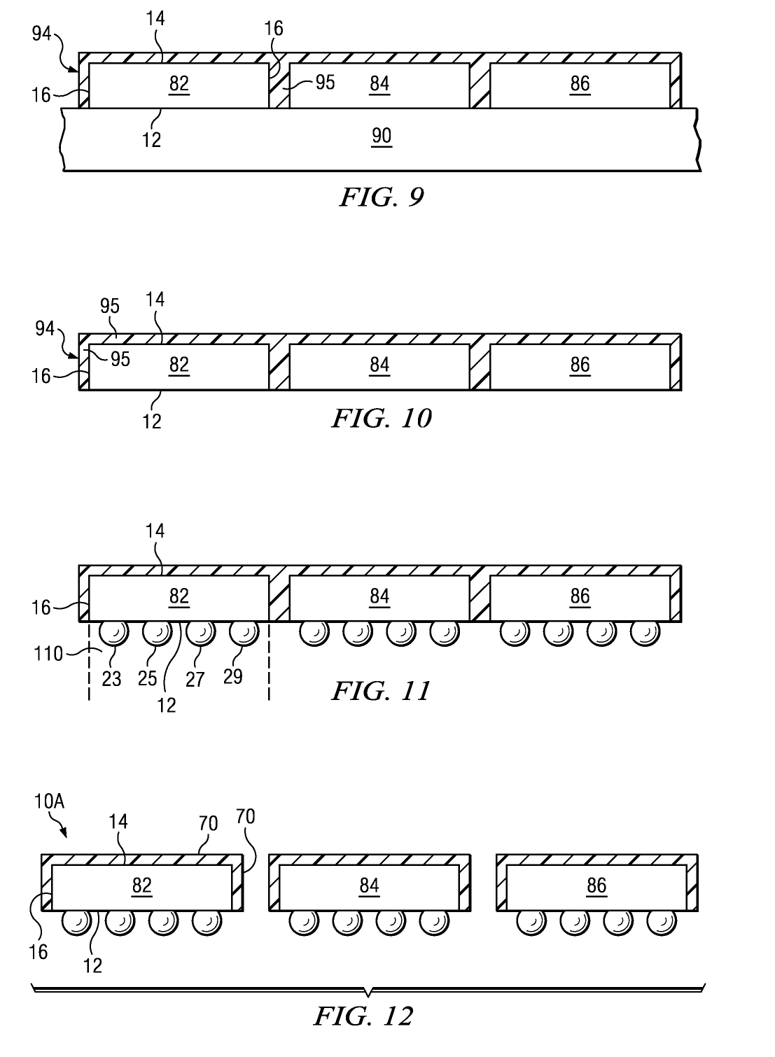

An encapsulation wafer 94, FIG. 8, is created through the molding process. A typical height of an encapsulation wafer 94 may be on the order of 300 μm, which may leave a thin layer of adhesive on top the second face 14 of each die as may be seen in FIG. 9. The thickness of the adhesive layer above face 14 in one nonlimiting embodiment is between about 30 μm and about 70 μm . However, the thickness of the adhesive layer on face 14 does not contribute to the “footprint” of the veneered die on a PC board and thus may vary considerably from the above range. A cross-sectional view of the encapsulation wafer 94 and dies 82, 84, 86 encapsulated thereby is illustrated in FIG. 9. (Microcracks 62 are not shown in dies 82, 84, 86 in FIG. 7-12, but it is to be understood that microcracks are present in at least some dies.) At this point in the process, the dies 82, 84, 86 are still weakly adhered to the carrier substrate 90. Next, as shown in FIG. 10, the carrier substrate 90 is peeled away from the dies leaving the first face 12 of each die exposed and with the second face 14 and side faces 16 covered with encapsulating material 95. As shown by FIG. 11, with the dies 82, 84, 86 still embedded within the encapsulation wafer 94, bump solder balls 23, 25, 27, 29, etc. are bonded to corresponding bond pads 36, FIG. 2 (Not visible in FIG. 11). The size of the bump solder balls and the position of the pads are such that the bump solder balls on each die are all positioned substantially completely within a region 110 that is a projection of the die periphery 52, FIG. 1, in a direction perpendicular to face 12. The attachment of bump solder balls to bond pads is well known to those skilled in the art and will thus not be further described herein. Next, the encapsulation wafer 94 is singulated into individual WCSP dies 10A as illustrated in FIG. 12. Singulation is accomplished by sawing the encapsulation wafer 94 along saw streets 96, 98, 100, 102, 106, 108, etc. that run between the dies as illustrated in FIG. 14. In one embodiment of the method, a single cut is made along each saw street. The dies in one embodiment are positioned sufficiently close so that a single saw cut down each saw street leaves only a thin veneer of adhesive on the side faces 16 of the dies. For example, the thickness of the adhesive veneer 70 on the side faces may be in a range between about 5 μm and 100 μm. Thus, this process does not significantly increase the “footprint” of the WCSP 10A, i.e., each WCSP 10A with veneer layer 70 is generally no more than 1.2 times as large as the WCSP 10 without the veneer. Also, since the addition of an adhesive layer 70 is done before other post singulation die handling and testing operations, microcracks in the walls are protectively sealed before further stresses are applied to the WCSPs, which could otherwise cause unsealed microcracks 62 to further propagate into the die circuitry 56.

FIG. 14 is a flow chart showing one embodiment of a method of making a wafer level chip size package. The method includes providing a die having a first face with a plurality of contact pads thereon, a second face opposite the first face and a plurality of side faces extending between the first face and the second face, at least one of the plurality of side faces having saw induced microcracks therein. The method further includes coating the at least one of the plurality of side faces having saw induced microcracks therein with a thin veneer of adhesives that penetrates the microcracks.

In the above specifically described embodiments bump solder balls are attached to bond pads of the die. It is to be understood that other types of electrical interfacing structure, such as copper pillars, could be used rather than bump solder balls. Similarly, an example of specific active side electrical connection layer structure, materials and dimensions have been given, but many other structures, materials and dimensions may be used on a WCSP, as would be apparent to those having skill in the art.

While various embodiments of the invention have been specifically described herein it is to be understood that the invention may be otherwise embodied and that the appended claims are to be construed to include such other embodiments, except as limited by the prior art.

1. A wafer level chip size package (WCSP) comprising:
a single die comprising a first face with a plurality of bonding pads thereon, a second face positioned opposite said first face and a plurality of side faces extending between said first face and said second face; and
a thin veneer of adhesive covering at least one of said second face and said plurality of side faces.

2. The WCSP of claim 1 wherein said at least one of said second face and said plurality of side faces comprise microcracks therein and wherein said thin veneer of adhesive extends into said microcracks, whereby opposite sidewalls of said microcracks are adhesively attached.

3. The WCSP of claim 2 wherein said thin veneer of adhesive is less than 100 μm thick.

4. The WCSP of claim 1 wherein said adhesive comprises epoxy molding compound.

5. The WCSP of claim 1 comprising a plurality of bump solder balls bonded to said plurality of bonding pads.

6. The WCSP of claim 5 wherein said first face comprises a peripheral edge and wherein said bump solder balls are all positioned inwardly of said peripheral edge.

7. The WCSP of claim 1 wherein said thin veneer of adhesive is a thin veneer of epoxy mold compound.

8. A method of making a wafer level chip size package (WCSP) comprising:
providing a die having a first face with a plurality of contact pads thereon, a second face opposite said first face and a plurality of side faces extending between said first face and said second face, at least one of said plurality of side faces having saw induced microcracks therein; and
coating said at least one of said plurality of side faces having saw induced microcracks therein with a thin veneer of adhesive that penetrates said microcracks.

9. The method of claim 8, wherein said coating with a thin veneer comprises coating with a veneer that is less than about 100 μm thick.

10. The method of claim 9 wherein said coating with a thin veneer of adhesive comprises coating with epoxy molding compound.

11. The method of claim 8 comprising: bonding a plurality of bump solder balls to said plurality of contact pads such that all of said bump solder balls are located in a region defined by projecting an outer peripheral edge of said first face in a direction perpendicular to said first face.

12. The method of claim 11 wherein said coating with a thin veneer comprises coating with a veneer of epoxy molding compound that is less than about 100 μm thick.

13. The method of claim 8 wherein coating the at least one of said plurality of side faces comprises coating all of said side faces.

14. The method of claim 13, further comprising coating said second face with adhesive.

15. A method of making wafer level chip size packages (WCSP's) comprising:
singulating a WCSP wafer into a plurality of singulated WCSP dies, each having a first face with a plurality of bonding pads thereon and an outer periphery, a second face positioned opposite said first face and a plurality of side faces extending between said first face and said second face;
mounting said singulated WSCP dies in a predetermined pattern at a predetermined spacing on a carrier substrate with said first face positioned adjacent to said carrier substrate;
encapsulating said singulated WSCP dies on said carrier substrate with an adhesive material so as to cover at least said side faces of each singulated WSCP dies to define an encapsulation wafer;
removing said carrier substrate from said encapsulation wafer;
attaching bump solder balls to contact pads on said singulated WSCP dies in said encapsulation wafer such that all of said bump solder balls attached to each said die are positioned substantially within a region defined by a projection of said outer periphery of said first face of said die; and
singulating said encapsulation wafer into a plurality of veneered dies each having a plurality of bump solder balls bonded to said first face thereof and a thin veneer of said adhesive material adhered to said side faces thereof.

16. The method of claim 15 wherein said singulating said encapsulation wafer comprises saw cutting said encapsulation wafer.

17. The method of claim 15 wherein said encapsulating said singulated WSCP dies with an adhesive material comprises encapsulating said dies with an adhesive material having a viscosity in a molten state which is sufficiently low to penetrate any microcracks in said side faces of said dies.

18. The method of claim 15 wherein said encapsulating said singulated WSCP dies with an adhesive material comprises encapsulating said dies with epoxy mold compound.

19. The method of claim 15 wherein said singulating said encapsulation wafer into a plurality of veneered dies each having a plurality of bump solder balls bonded to said first face thereof and a thin veneer of said adhesive material adhered to said side faces thereon comprises singulating said wafer so that said thin veneer of adhesive material adhered to said side faces is no more than about 100 μm thick.

20. The method of claim 15 wherein said singulating said encapsulation wafer into a plurality of veneered dies each having a plurality of bump solder balls bonded to said first face thereof and a thin veneer of said adhesive material adhered to said side faces thereon comprises singulating said encapsulation wafer so that said thin veneer of adhesive material makes the footprints of said veneered dies no more than about 1.2 times larger than the footprints of said singulated WCSP dies.
